(19) United States
(12) Patent Application Publication
(10) Pub. No.: US 2024/0224727 A1
(43) Pub. Date: Jul. 4, 2024

(54) Display Device and Method for Manufacturing the Same

(71) Applicant: LG Display Co., Ltd., Seoul (KR)

(72) Inventor: Haun-Min Lee, Paju-si (KR)

(21) Appl. No.: 18/397,401

(22) Filed: Dec. 27, 2023

(30) Foreign Application Priority Data
Dec. 30, 2022 (KR) 10-2022-0191294

(51) Int. Cl. H10K 59/80; H10K 102/00

(52) U.S. Cl. CPC H10K 59/873; H10K 59/8794; H10K 2102/311; H10K 2102/331

(57) ABSTRACT

There is disclosed a display device that may protect a display panel in a bending area by forming a protection member including metal nanoparticles, and a method for manufacturing the same. To realize that, the display device comprising a display panel include a first area, a second area, a bending area and a bezel area, a cover member disposed on the display panel, a protection member disposed outside of the display panel in the bending area, a reinforcing member disposed outside of the protection member in the bending area, a back frame disposed under the reinforcing member, under the cover member, and under the bent display panel, so that the display device may improve module rigidity by preventing panel lifespan decrease and crack of the bending area and secure reliability by preventing quality defect, thereby realizing narrow bezel.

### CROSS-REFERENCE TO RELATED APPLICATION

This application claims priority to and the benefit of Republic of Korea Patent Application No. 10-2022-0191294, filed on Dec. 30, 2022, which is incorporated by reference in its entirety.

### TECHNICAL FIELD

The present disclosure relates to a display device, more particularly, a display device and a method for manufacturing the same.

### BACKGROUND

A display device includes a display area (or an active area) displaying an image and a non-display area (or a dead space or a bezel area) formed along an edge space of the display area. The display device requires various additional components such as a driving integrated circuit or a circuit board in addition to a display panel for displaying a screen.

In the non-display area, additional components may be disposed or various connecting parts such as a flexible printed circuit board for connecting the additional components may be disposed.

The non-display area of the display device may be called ‘bezel’. When the bezel is thick, a user's gaze could be dispersed. If the bezel becomes thin, the user's gaze can be fixed on the screen in the display area, thereby increasing immersion.

### SUMMARY

To secure a broad active area and a reduced bezel area of the display device as possible, various other components such as a driving integrated circuit or a circuit board as well as a pad part of the display panel are disposed on a rear surface of the display panel. The above various additional components are mounted on or connected with connecting components, such as a flexible printed circuit, through an inside of a cover member, thereby forming a module.

Such the various additional components may be protected from drop or damage of the module by a back frame attached to the cover member. The back frame may also prevent foreign substances or moisture from penetrating into the module.

However, when an impact due to the user's environment such as external shock or drop is applied to the back frame formed of metal, the back frame might be deformed enough to apply a blow to a bending portion which results in pattern crack and screen abnormalities.

Accordingly, the display device cannot secure reliability due to occurrence of quality abnormalities in the display device so the display device might have a problem of limitation of realizing a stable narrow bezel.

Accordingly, one objective of the present disclosure is to solve the above-noted disadvantages of the prior art, and to provide a display device that may realize a narrow bezel by protecting a display panel disposed in a bending portion through a protection member including a metal nanoparticles to prevent quality abnormalities and secure reliability.

Another objective of the present disclosure is to provide a display device that may improve rigidity of a module by using a protection member to prevent lifespan reduction of a display panel and crack of a bending portion.

A further objective of the present disclosure is to provide a method for manufacturing a display device that may prevent panel crack and damage due to high intensity UV irradiation during a manufacturing process by forming a back frame made of a polymer epoxy resin after applying a protection member including a metal nanoparticles on an outer surface of a reinforcing member for reinforcing bending of a display panel.

Objects of the present invention are not limited to the above-described objects, and other objects and advantages of the present invention will be understood by the following description and will be more definitely understood through the embodiments of the present invention. It is also to be easily understood that the objectives and advantages of the present invention may be realized and attained by means and a combination thereof described in the appended claims.

A display device according to an embodiment of the present disclosure may include a display panel comprising a first area, a second area, a bending area and a bezel area; a cover member disposed on the display panel: a protection member disposed outside of the display panel in the bending area: a reinforcing member disposed outside of the protection member in the bending area: and a back frame disposed under the reinforcing member, under the cover member, and under the bent display panel.

In another aspect of the present disclosure, a display device according to an embodiment may include a display panel comprising a first area, a second area, a bending area and a bezel area: a cover member disposed on the display panel: a reinforcing member disposed outside of the display panel in the bending area: and a back frame disposed under the reinforcing member, under the cover member, and under the bent display panel. The reinforcing member may include a metal nanoparticle layer disposed therein.

A method for manufacturing a display device according to an embodiment of the present disclosure may include (a) disposing a display panel on a first back plate and a second back plate with a bending area interposed therebetween: (b) disposing a protection member on the display panel: (c) disposing a reinforcing member on the protection member; (d) bending the display panel: (e) disposing a connection member between the second back plate on the bent display panel and the first back plate and seating the bent display panel: (f) disposing a back frame under the reinforcing member, under the bezel area of the cover member, and under the second area and the bending area of the display panel.

According to the embodiments of the present disclosure, the back frame of the panel may be formed after applying the protection member outside the reinforcing member of the bending area panel in the process of manufacturing the display device, thereby reducing an influence of high-intensity UV light irradiation.

In addition, according to the embodiments of the present disclosure, the amount of the high-intensity UV light irradiation to the bending area of the display panel may be reduced, thereby preventing crack and damage of the panel.

In addition, according to the embodiments of the present disclosure, the compression rigidity of the panel bending area may be improved by preventing the panel crack and damage, thereby preventing lifespan reduction of the panel.

In addition, according to the embodiments of the present disclosure, the back frame of the display device may be made of polymer epoxy resin. Accordingly, air gap inside the module may be removed and the rigidity of the module may be secured, thereby realizing a stable narrow bezel.

In addition, according to the embodiments of the present disclosure, the panel crack and damage may be prevented by the cushion effect of the polymer epoxy resin when an external shock is applied to the panel bending area, thereby providing a long-lifespan low-power-consumption display device.

According to the method for manufacturing the display device, the panel bending area may be protected by the protection member and decrease in panel lifespan may be mitigated, thereby realizing quality improvement of the display device.

The display device according to the embodiments of the present disclosure may improve the quality and secure reliability by preventing panel crack and securing the module rigidity, thereby realizing narrow bezel.

Aspects according to the present disclosure are not limited to the above ones, and other aspects and advantages that are not mentioned above can be clearly understood from the following description and can be more clearly understood from the embodiments set forth herein.

In addition to the above-described effects, specific effects of the present invention will be described together with the following detailed description for implementing the present invention.

### BRIEF DESCRIPTION OF DRAWINGS

FIG. 1A is a front view of a display device according to an embodiment of the present disclosure;

FIG. 1B is a rear view of a display device according to an embodiment of the present disclosure;

FIG. 2 is a sectional view along a line 2 of FIG. 1A according to an embodiment of the present disclosure;

FIG. 3 is a view showing an example of forming a protection member according to an embodiment of the present disclosure;

FIG. 4 is a view schematically showing a method for manufacturing a protection member according to an embodiment of the present disclosure;

FIG. 5 is a graph showing a ultraviolet (UV) reflectance of metals according to an embodiment of the present disclosure;

FIG. 6 is a view showing a method of manufacturing a display device according to an embodiment of the present disclosure; and

FIG. 7 is a view showing a process of manufacturing a back frame according to an embodiment of the present disclosure.

### DETAILED DESCRIPTION

The above-described aspects, features and advantages are specifically described hereunder with reference to the accompanying drawings such that one having ordinary skill in the art to which the present disclosure pertains can easily implement the technical spirit of the disclosure. In the disclosure, detailed descriptions of known technologies in relation to the disclosure are omitted if they are deemed to make the gist of the disclosure unnecessarily vague. Below, preferred embodiments according to the disclosure are specifically described with reference to the accompanying drawings. In the drawings, identical reference numerals can denote identical or similar components.

It will be understood that when an element is referred to as being “connected with” or “coupled to” another element, the element can be directly connected with the other element or intervening elements may also be present. In contrast, when an element is referred to as being “directly connected with” another element, there are no intervening elements present.

Terminology that is used in the present disclosure (including technical and scientific terms) is limited to only for embodiments herewith but made only to make it easy to understand the present disclosure. Unless defined otherwise, all terms used herein, including technical or scientific terms, have the same meaning as commonly understood by a person skilled in the art to which this invention pertains.

Hereinafter, a display device that may secure rigidity of a module and improve module quality by protecting a bending portion of a panel through a protection member, and a method for manufacturing the display device will be described.

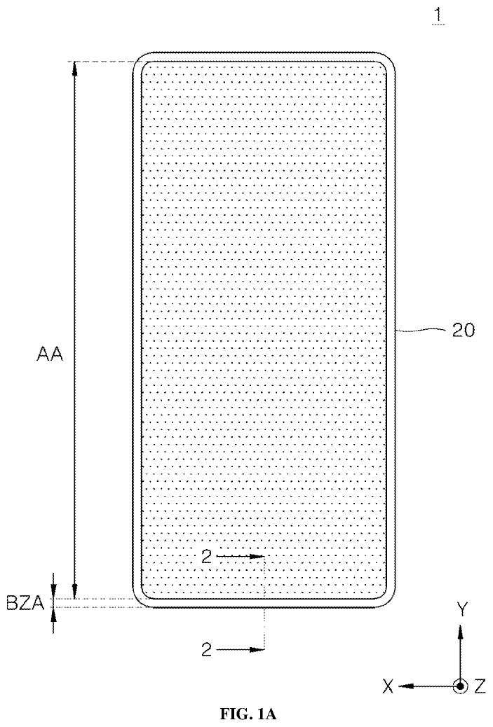

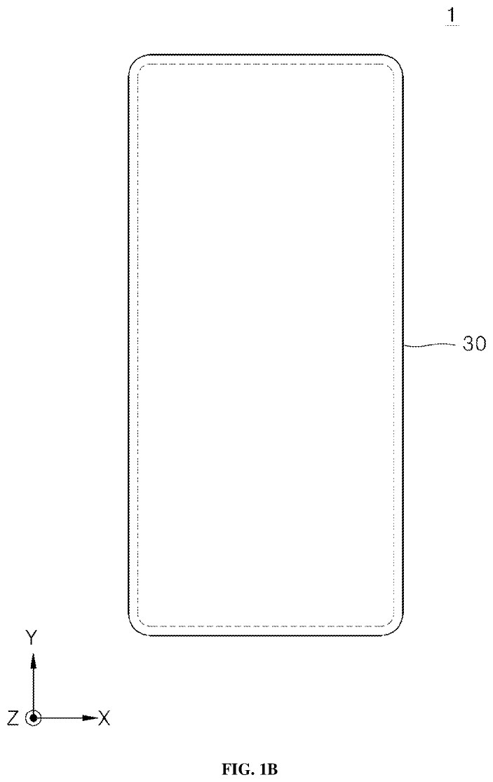

FIG. 1A is a front view of a display device according to an embodiment of the present disclosure. FIG. 1B is a rear view of a display device according to an embodiment of the present disclosure.

FIG. 1A schematically shows a front surface of the display device 1 on which an active area AA is disposed. FIG. 1B schematically shows a rear surface of the display device 1.

A direction toward a front surface and an upper direction, which are defined in the present disclosure, means a Z-axis and a direction toward a rear surface and a lower direction means a −Z-axis.

Referring to FIGS. 1A and 1B, the display device 1 according to the present disclosure may include a cover member 20 disposed on a front surface and a back frame 30 disposed on a rear surface.

The cover member 20 may include a cover window and a cover glass.

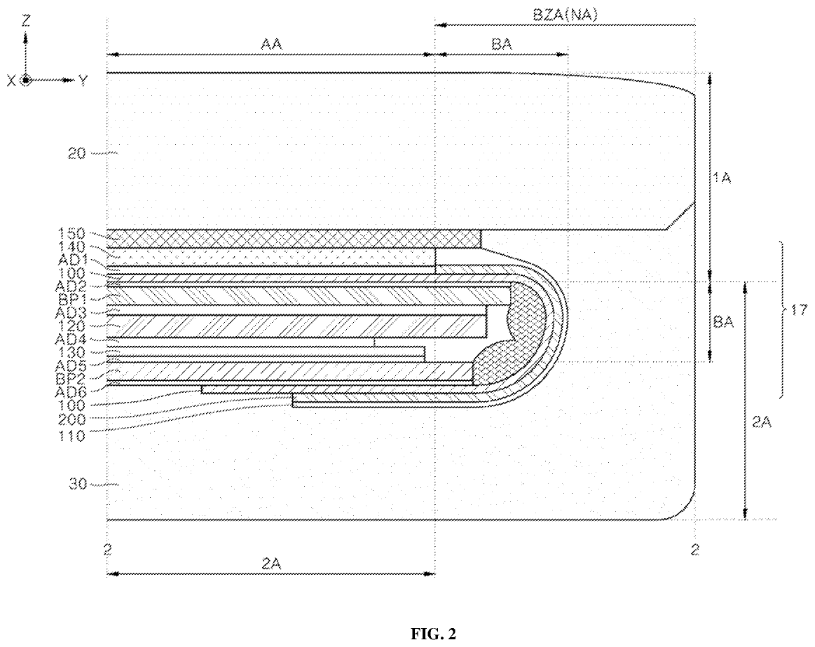

A display module may be disposed between a rear surface of the cover member 20 and an upper surface of the back frame 30. Here, the display module, which will be described in detail referring to FIG. 2, may include a flexible plate, a back plate, a reinforcing member, a protection member, a connection member and etc.

The display device 1 may include an active area AA and a bezel area BZA, which are provided on a front surface. The bezel area BZA may be disposed along an outermost area of the display device 1 as surrounding the active area AA.

The cover member 20 may be disposed to cover a front surface of the display module and protect the display module from external impact.

An edge area of the cover member 20 may be rounded toward a rear surface on which the display module is disposed.

In this instance, the cover member 20 may be disposed to cover even at least predetermined area of a lateral surface of the display module disposed on the area surface so that it may protect the lateral surface as well as the front surface of the display module from external impact.

Since it includes the active area AA for displaying a screen, the cover member 20 may be made of a transparent material such as a cover glass to display an image. For example, the cover member 20 may be made of a transparent plastic material, a glass material or a tempered glass material.

Referring to FIGS. 2 to 5, the display device according to an embodiment of the present disclosure may include a display module 17, a cover member 20, and a back frame 30.

FIG. 2 is a sectional view along a line 2 of FIG. 1A according to an embodiment of the present disclosure.

Referring to FIG. 2, the display device 1 according to an embodiment of the present disclosure may include a display module 17, a cover member 20, and a back frame 30.

The display device 1 may include a display panel 100, the cover member 20 disposed on the display panel 100, and the back frame 30 provided below the display panel to support the display panel 100 and the cover member 20.

The back frame 30 may be disposed on the rear surface of the display module 17 to accommodate the display module 17 and it may become into contact with the cover member 20 to support the cover member 20.

The back frame 30 may serve as a housing that forms an outer rear surface of the display device 1, and may be made of a metal material or a polymer epoxy resin. However, embodiments of the present disclosure are not limited thereto.

In this instance, the back frame 30 may function as a case for defining an outermost portion of the display device 1 but the embodiments of the present disclosure are not limited thereto. For example, the back frame 30 may serve as a middle frame configured of a housing protecting a rear surface of the display module.

The display device 1 may include a display panel 100, a cover member 20 disposed on the display panel 100, and a back frame 30 supporting the display panel 100 and the cover member 20 at a position below the display panel 100.

A front surface of the cover member 20 may be divided into an active area AA and a non-display area NA that is the other area than the active area AA. The non-display area NA may be formed along an edge area of the active area AA on the front surface of the cover member 20, and it may include a bezel area BZA.

A rear surface of the cover member 20 may include a non-display area NA.

The display module coupled to the rear surface of the cover member 20 may have a bending area BA. The bending area BA may be disposed in the bezel area BZA provided on the rear surface of the cover member 20 in a −Z-axis.

To reduce the bezel area BZA, the radius of curvature of the bending area BA needs to be reduced.

The radius of curvature of the bending area BA may be proportional to the total thickness of the display module 17 and the display device 1. When the total thickness increases, the radius of curvature of the bending area BA increases. When the total thickness decreases, the radius of curvature of the bending area BA decreases.

Accordingly, not to increase the size of the bezel area BZA, it is necessary not to increase the total thickness of the display module 17 and the display device.

FIG. 2 shows a sectional view cut away along line 2 from FIG. 1A. The display device 1 shown in FIG. 2 may include the display module 17, the cover member 20 disposed on an upper surface of the display module 17, and the back frame 30 supporting the display module 17 and the cover member 20 at a position below the display module 17.

The display module 17 may include the display panel 100. The display module 17 may include the structure from an upward optical control layer 140 to a downward reinforcing member 110 with respect to the display panel 100. The display panel 100 may have a flexible plate. The display panel 100 may include the active area AA and a bezel area BZA on the front surface. The bezel area BZA may have a bending area BA. The display panel 100 may include a first area 1A that is a front surface of the display panel 100 and a second area 2A that is a rear surface of the display panel 100 in a vertical direction.

The bending area BA may be provided between the first area 1A and the second area 2A in the vertical direction. The bending area BA may be disposed between the first area 1A and the second area 2A, while partially overlapping with the second area 2A.

Accordingly, the display device 1 may include the first area 1A as a front surface, the second area 2A as a rear surface, and a display panel 100 disposed on a rear surface of the first area 1A by bending at the bending area BA.

The first area 1A may have a vertical structure from the display panel 100 for displaying an image to the cover member 20 disposed in the upward direction.

The second area 2A may have a structure from the display panel 100 to the back frame 30 in a downward direction in which an image is not displayed.

On the display module 17 in the first area 1A, an optical control layer 140 may be disposed on the display panel 100 through a first adhesive layer AD1 and the cover member 20 may be disposed on the optical control layer 140 through an optical adhesive layer 150. In one embodiment, the optical control layer 140 may include a polarizing layer, for example. The optical control layer 140 may not be an essential component in the embodiment of the present disclosure and may not be provided. The embodiments of the present disclosure are not limited thereto. A black matrix may be disposed on a rear surface of the cover member 20. The black matrix may be disposed in the non-display area NA or the bezel area BZA, which are the areas where light does not transmit, and it may serve to prevent light leakage.

A first support member (hereinafter, a first back plate BP1) may be disposed under the display panel 100 through a second adhesive layer AD2 and a plate 120 may be disposed under the first back plate BP1 through a third adhesive layer AD3. A connection member 130 may be disposed under the plate 120 through a fourth adhesive layer AD4 and a second support member (hereinafter, a second back plate BP2) may be disposed under the connection member 130 through a fifth adhesive layer AD5. The bent display panel 100 may be disposed under the second back plate BP2 through a sixth adhesive layer AD6. Here, the bent reinforcing member 110 may be disposed under the bent display panel 100. For example, the connection member 130 may be a bezel bending fixing tape 130. However, the present disclosure is not limited thereto.

Referring to FIG. 2, the display device 1 according to an embodiment of the present disclosure may include the display panel 100, the cover member 20, a reinforcing member 110, a protection member 200 and the back frame 30.

The cover member 20 may be disposed on the display panel 100 and include a bezel area BZA having a bending area BA and a first area 1A having an active area AA.

The reinforcing member 110 may be disposed on an outer area of the display panel 100 in the bending area BA.

The back frame 30 may be disposed under the protection member 200, under the cover member 20 and under the bent display panel 100.

The back frame 30 may support the protection member 200, support the bezel area BZA of the cover member 20, and support the first area 1A, the second area 2A and the bending area BA of the display panel 100. To this end, the back frame 30 may be in contact with the bezel area BZA of the cover member 20, with the second area 2A of the display panel 100, and the protection member 200 of the bending area BA.

The back frame 30 may include a polymer epoxy resin. The polymer epoxy resin may include a polymer epoxy-based resin and it may be referred to as “an epoxy resin” or a “resin”.

The back frame 30 may have a flat lower surface and a vertical surface protruding vertically from an edge of the lower surface. The lower surface of the back frame 30 may be bonded to a rear surface of the reinforcing member 110 by adhesive means such as a resin or a tape, but the embodiments of the present disclosure are not limited thereto. For example, an upper end of a lateral wall, which is an upper end of the vertical surface of the back frame 30, may be bonded to the cover member 20 by a double-sided tape.

The back frame 30 may have a box shape with an open top, and accommodate the display module 17. The display module 17 may include the display panel 100.

Since the back frame 30 according to this embodiment of the present disclosure is made of a polymer epoxy resin, the bent display module 17 may be protected thinner and more effectively and narrow bezel may be realized in the display device 1 accordingly.

Since the back frame 30 according to the embodiment of the present disclosure is made of the polymer epoxy resin, micro fluidity of modules may not occur without an air gap between the modules including the display panel 100 of the display device 1 and durable fixation may be realized accordingly.

The display panel 100 may include a first area 1A, a second area 2A, and a bezel area BZA including a bending area BA.

The first area 1A may include an active area AA of the display panel 100. The second area 2A may include a bent display panel 100. The first area 1A and the second area 2A may be disposed to face each other in a vertical direction (i.e., a Z-direction).

The display panel 100 may have a flat shape in the first area 1A. The display panel 100 may have a bent shape in the bending area BA in a downward direction (i.e., the Z-direction) and a flat shape in an inward direction from the bending area BA in the second area 2A.

A first back plate BP1 may be disposed under the display panel 100. The first back plate BP1 may support the first area 1A of the display panel 100 and the display panel 100 of the bending area BA. For that, the first back plate BP1 may have an upper surface that is in contact with a lower surface of the display panel 100 through a second adhesive layer AD2.

The first back plate BP1 may be disposed on the lower surface of the display panel 100 to supplement the rigidity of the display panel 100 and maintain a flat state of the display panel located on the front surface.

The first back plate BP1 and the second back plate BP2 may have a predetermined strength and thickness to supplement the rigidity of the display panel 100.

Since the first back plate BP1 is formed with the above-mentioned predetermined strength and thickness to supplement the rigidity of the display panel 100, there may be no first back plate BP1 in the display panel 100 bent in the bending area BA to have a shape of a curved surface in one embodiment.

In the display device 1, the second back plate BP2 may be disposed in the second area 2A of the display panel 100. The second back plate BP2 may be disposed on the bent display panel 100.

The second back plate BP2 may support the display panel 100 in the second area 2A. To this end, the second back plate BP2 may have a lower surface that is in contact with the upper surface of the bent display panel 100 so that it may be bonded to the upper surface of the bent display panel 100 by a sixth adhesive layer AD6.

The second back plate BP2 may be spaced apart by a preset distance from the first back plate BP1 to be disposed on the display panel 100 in the second area 2A.

With respect to the state before the display panel 100 is bent, the second back plate BP2 may be disposed under the display panel 100, spaced apart from the first back plate BP1. The second back plate BP2 may be disposed under the display panel 100 to keep the flat state of the display panel 100, while supplementing the rigidity of the display panel 100. Since it is formed with the predetermined strength and thickness to supplement the rigidity of the display panel, the second back plate BP2 may not be formed in an area of the display panel 100 corresponding to some area of the bending area BA. However, embodiments of the present disclosure may not be limited thereto.

After the display panel 100 is bent, the second back plate BP2 may be disposed on the display panel 100 in the second area 2A.

A plate 120 having a flat shape may be disposed between the first back plate BP1 and the second back plate BP2.

The plate 120 may include metal to reinforce the supporting capacity of the first and second back plates BP1 and BP2, for example. Alternatively, the plate 120 may include one of stainless-steel SUS, glass, ceramic and metal or a combination thereof. The plate 120 may be made of a plastic material including at least one of polycarbonate PC, polyimide PI, polyethylene naphthalate PEN, or polyethylene terephthalate PEP.

The first back plate BP1 may be bonded to an upper surface of the plate 120 by a third adhesive layer AD3.

A connection member 130 (i.e., bezel bending fixing tape 130) may be disposed under the plate 120. The bezel bending fixing tape 130 may fix the bezel bending.

The bezel bending fixing tape 130 for fixing the bent display panel 100 between the first area 1A and the second area 2A may be disposed between the second back plate BP2 and the plate 120. The bezel bending fixing tape 130 may be bonded to the plate 120 by a fourth adhesive layer AD4 and to the second back plate BP2 by a fifth adhesive layer AD5.

When the bending is performed in the bending area BA to locate a pad PAD of the display panel 100 under the front surface of the display panel 100, that is, a rear surface of the display panel 100, a restituting force intended to restitute the display panel 100 to a state before the bending may be strongly applied.

When the restituting force is strongly applied to the display panel 100, a lifting phenomenon might occur in which the pad PAD of the bent display panel 100 could not be fixed to be lifted.

The bezel bending fixing tape 130 may be disposed between the front surface and the pad PAD of the display panel 100 and configured to fix the bent display panel 100 to maintain the bent state of the display panel 100.

The bezel bending fixing tape 130 may be formed with a predetermine thickness and it may be a double-sided tape having a strong adhesive force capable of fixing the front surface of the display panel 100 and the pad PAD.

The bezel bending fixing tape 130 may be configured of at least one layer made of at least one material of optical clear adhesive OCA, optical clear resin OCR and pressure sensitive adhesive PSA.

The bezel bending fixing tape 130 may include a tape including a foam tape or a foam pad to have a shock absorbing function or a double-sided tape having conductivity. For example, the double-sided conductive tape may include an upper adhesive layer, a lower adhesive layer and a conductive layer disposed between the upper adhesive layer and the lower adhesive layer. The adhesive layer may also include a conductive material.

The bezel bending fixing tape 130 may be bonded to the plate 120 by a fourth adhesive layer AD4. At this time, the plate 120 may include an embossed layer in contact with the first back plate BP1, a cushion layer disposed under the embossed layer and having a shock absorbing function, and a heat dissipation layer disposed under the cushion layer and having a heat dissipation function.

A protection member 200 may be disposed on an outer surface of the display panel 100 in some area of the second area 2A and the bending area BA. The protection member 200 may include metal nanoparticles. The metal nanoparticles may include silver Ag or aluminum Al.

The protection member 200 may extend to cover the display panel 100 of the bending area BA, specifically, a portion (predetermined area) of the display panel 100 of the first area BA in contact with the bending area BA and even the display panel 100 of the second area 2A.

In FIG. 2, a reinforcing member 110 for reinforcing the bending of the display panel 100 may be disposed on the outside of the protection member 200 of the bending area BA. Here, the reinforcing member 100 may include a micro coating layer, for example. The micro coating layer MCL may be referred to as a micro cover layer MCL.

The reinforcing member 110 may extend to cover the protection member 200 of the bending area BA, cover a portion (an area) of the protection member 200 of the first area 1A in contact with the bending area BA, and cover even the protection member 200 of the second area 2A.

The reinforcing member 110 may include resin such as an ultraviolet curable acrylic resin. However, embodiments of the present disclosure are not limited thereto.

The reinforcing member 110 may be formed of a cured resin material that has undergone a curing process after coating the resin. If it is used as an ultraviolet curable resin, the resin may be cured by ultraviolet rays.

The reinforcing member 110 may be disposed outside of the display panel 100 to cover various signal lines between the encapsulation part and the pad of the display panel 100. Accordingly, the reinforcing member 110 may protect the signal lines from external shock and prevent penetration of moisture into the signal lines.

Since it is disposed outside the display panel 100 in the bending area BA, the reinforcing member 110 may supplement the rigidity of the display panel 100 in the bending area BA where the bezel bending fixing tape is removed. The bezel bending fixing tap may be bonded to a lower surface of the display panel 100 and bent together. When the bending area BA is removed after the bending, the first back plate BP1 may remain under the display panel 100 of the first area 1A and the second back plate 2 may remain on the display panel 100 bent in the second area 2A. Accordingly, the display panel 100 of the bending area BA where the bezel bending fixing tape is removed may have deteriorated rigidity so that the reinforcing member 110 attached to the outside may compensate the rigidity of the bending area BA.

The display device 1 shown in FIG. 2 may have following components that are multi-layered between the first area 1A and the second area 2A in a vertical direction (i.e., Z-direction).

For example, the bent reinforcing member 110 and the bent protection member 200 may be disposed on the back frame 30. The bent display panel 100 may be disposed on the protection member 200 and a sixth adhesive layer AD6 may be disposed on the bent display panel 100.

The second back plate BP2 may be disposed on the sixth adhesive layer AD6 and a fifth adhesive layer AD5 may be disposed on the second back plate BP2. The bezel bending fixing tape 130 may be disposed on the fifth adhesive layer AD5.

A fourth adhesive layer AD4 may be disposed on the bezel bending fixing tape 130 and the plate 120 may be disposed on the fourth adhesive layer AD4. A third adhesive layer AD3 may be disposed on the plate 120.

The first back plate BP1 may be disposed on the third adhesive layer AD3 and a second adhesive layer AD2 may be disposed on the first back plate BP1. The flat display panel 100 may be disposed on the second adhesive layer AD2.

A first adhesive layer AD1 may be disposed on the flat display panel 100 and an optical control layer 140 may be disposed on the first adhesive layer AD1. An optical clear adhesive layer 150 may be disposed on the optical control layer 140 and the cover member 20 may be disposed on the optical clear adhesive layer 150.

The cover member 20 may protect the display panel 100 from external shock and transmit the light emitted from the display panel 100, so that an image displayed on the display panel 100 may be viewed from the outside.

The cover member 20 may be made of a material having impact resistance and light transmittance such as polymethylmethacrylate (PMMA), polycarbonate (PC), cycloolefin polymer (COP), polyethylene terephthalate (polyethylene terephthalate, PET), PI (Polyimide), or PA (Polyaramid). However, embodiments of the present disclosure are not limited thereto.

The optical clear adhesive layer 150 may have a thickness of 100 to 300 μm, for example. If the optical clear adhesive layer 150 has a thickness of 100 μm or less, the adhesive force could become weakened so that it is difficult to modularize the cover member 20 and the first and second back plates BP1 and BP2. If the optical clear adhesive layer 150 has a thickness of 300 μm or more, it may be difficult to bend the display device 1 disadvantageously. Accordingly, the optical clear adhesive layer 150 may have a thickness of 100 to 300 μm.

The optical control layer 140 may prevent deterioration of a contrast ratio CR due to external light. In the display device 1 according to the present disclosure, a polarization layer 140 for blocking external light incident from the outside may be disposed on an OLED panel in a transmission direction of the light emitted through the display panel, thereby improving the contrast ratio.

When cutting the back plate of the bending area BA with respect to one back plate disposed in the first area 1A, the bending area BA and the second area 2A, the first back plate BP1 may be positioned on the plate 120 under the display panel 100 of the first area 1A and the second back plate BP2 under the flat plate 120 may be positioned in the second area 2A on the rear surface of the display panel 100.

Here, the display panel 100 is exposed in the bending area BA by cutting and removing the back plate of the bending area BA. After that, the reinforcing member 110, the protection member 200 and the display panel 100 of the bending area BA may be bent to be bonded to the bezel bending fixing tape 130 through the second back plate BP2 in contact.

The reinforcing member 110 may improve deformation of the display panel 100 in the bending area BA and facilitate the bending of the display panel 100 at a constant curvature. The reinforcing member 110 may be configured of a resin layer to compensate for a decrease in the rigidity due to the bending of the display panel in the bending area BA. The reinforcing member 110 may be made of polymer such as polyimide (PI) or polyethylene terephthalate (PET). When the reinforcing member 110 is a polymer film, the reinforcing member 110 may have a modulus of about 1 to about 10 Gpa. However, embodiments of the present disclosure are not limited thereto.

In FIG. 2, the back frame 30 may include metals. Accordingly, the back frame 30 made of a metal material may accommodate various components such as the display panel 100 disposed on the rear surface of the cover member 20 and protect them.

Meanwhile, the back frame 30 is made of a plastic material such as resin with shock absorbing function. In this instance, when an external shock with a preset pressure or more is applied to the back frame 30, the plastic material having the shock absorbing function may absorb the external shock.

Accordingly, no crack occurs in the display panel 100 due to the shock absorbing function of the back frame 30, thereby protecting display panel 100.

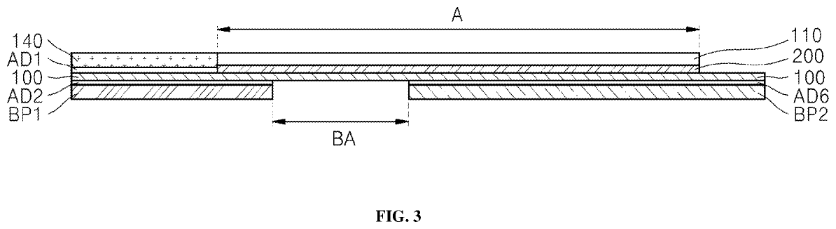

FIG. 3 is a view showing an example of forming a protection member 200 according to an embodiment of the present disclosure.

Referring to FIG. 3, the protection member 200 according to this embodiment of the present disclosure may be disposed on the display panel 100. The protection member 200 may be disposed on the display panel 100 and the reinforcing member 110 may be disposed on the protection member 200.

In this instance, the display panel 100 may be disposed on upper surfaces of the first back plate BP1 and the second back plate BP2 that have the bending area BA interposed therebetween.

The structure multilayered in an upper direction of the first back plate BP1 is as follows. The second adhesive layer AD2 may be disposed on the first back plate BP1 and the display panel 100 may be disposed on the second adhesive layer AD2. The first adhesive layer AD1 and one side of the protection member 200 may be disposed on the display panel. The optical control layer 140 and one side of the reinforcing member 110 may be disposed on an upper surface of the first adhesive layer AD1 and an upper surface of one side of the protection member 200.

The structure multilayered in an upper direction of the second back plate BP2 is as follows. The sixth adhesive layer AD6 may be disposed on the second back plate BP2 and the other side of the display panel 100 may be disposed on the sixth adhesive layer AD6. The other side of the protection member 200 may be disposed on an upper surface of the other side of the display panel 100. The other side of the reinforcing member 110 may be disposed on an upper surface of the other side of the protection member 200.

The protection member 200 may include metal nanoparticles. For example, the metal nanoparticles may be aluminum Al and silver Ag nanoparticles.

In case where the reinforcing member 110 is a micro coating layer MCL, a mixture solution of the micro coating layer MCL and metal nanoparticles may be applied when the protection member 200 is disposed on or under the reinforcing member 110. At this time, the contents of the micro coating layer may include an acrylic resin.

As the protection member 200 and the reinforcing member 110 are coated on the display panel 100, the amount of ultraviolet rays irradiated to the bending area BA of the panel 100 may be reduced when irradiating high-intensity ultraviolet UV rays and the local stiffness near the bending area BA may be improved.

In addition, when irradiating the high-intensity ultraviolet UV rays, the damage applied to a weak area of the panel compared to the other areas of the module may be reduced by 10% with respect to the prior art. Also, the reduction in the lifespan of the panel may be alleviated.

The metal nanoparticles contained in the protection member 200 may be applied to a thickness of about 60 micrometers (i.e., μm) including the reinforcing member 110, for example.

The protection member 200 may be coated on the reinforcing member 110 to a length of 2.6 mm and a thickness of 60 μm, for example.

When being disposed on the reinforcing member 110, the protection member 200 may be disposed on the same layer with the polarization layer 140 disposed on the display panel 100 through the first adhesive layer AD1.

The protection member 200 may be disposed to a length of about 1.428 mm, for example, when disposed under the bent display panel 100 in the second area 2A in a horizontal direction by being bent in the bending area BA together with the display panel 100 and the reinforcing member 110. The length of the bent protection member 200 according to the embodiments of the present disclosure is not limited thereto, and it may be modified based on each model.

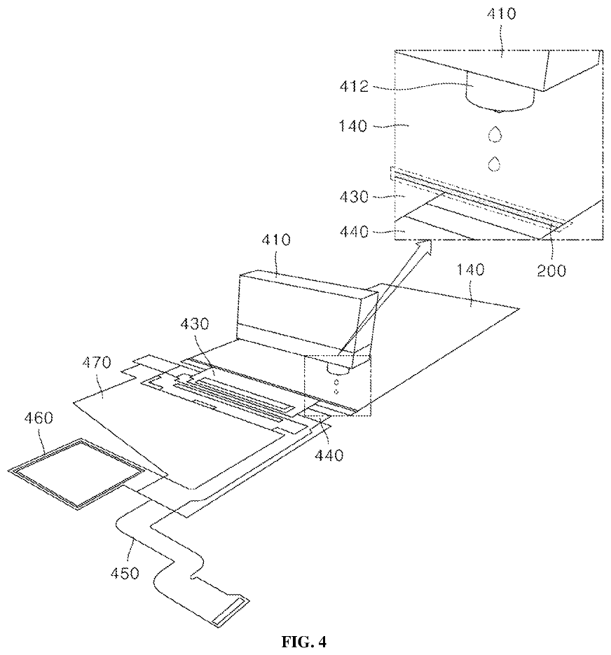

FIG. 4 is a view schematically showing a device of manufacturing a protection member according to an embodiment of the present disclosure.

Referring to FIG. 4, the device according to the embodiment of the present disclosure may include jet valve 410 and an applicator nozzle 412.

The protection member 200 may be disposed on the same layer with the optical control layer 140 as shown in FIG. 3.

Accordingly, a process of forming the protection member 200 will be performed in a state where a chip-on-film COF 430, flexible printed circuit boards FPCB 440, 450 and 460 are disposed.

The protection member 200 may be formed by applying a mixture solution of resin, aluminum Al nanoparticles through the applicator nozzle 412 in a state where the jet valve 410 is positioned at an end of the optical control layer 140.

Resin is a material used in forming the reinforcing member 110 as the micro coating layer. For example, in the mixture solution of resin and metal nanoparticles, the metal nanoparticles may be coated with a thickness of about 6 μm with 10 vol % of the metal nanoparticles and a thickness of 60 μm as a whole including the reinforcing member 110.

Here, vol % is a physical unit of volume and represents the ratio of a substance to 100% of a unit volume. Accordingly, the fact that the metal nanoparticles are 10 vol % indicates that the metal nanoparticles account for as much as 10% in 100% of the mixture solution.

The protection member 200 formed in the above-noted process includes the metal nanoparticles so that ultraviolet light may be reflected by the metal nanoparticles when irradiated with high-intensity ultraviolet UV light.

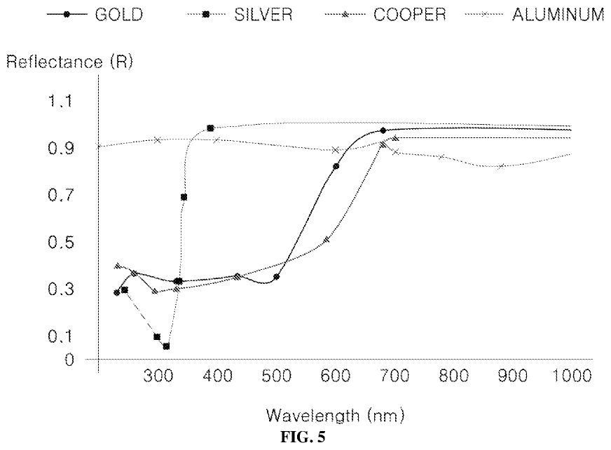

For example, FIG. 5 shows that the metal nanoparticles such as aluminum Al or silver Ag showed to have higher UV reflectance than other metal nanoparticles in a resin curing UV irradiation wavelength range of 350 nm to 460 nm. FIG. 5 is a view showing UV reflectance of other metals. It is shown that the aluminum and silver nanoparticles have a reflectance close to 0.9 when the wavelength λ of ultraviolet light is 350 nm to 460 nm. Accordingly, it is shown that aluminum and silver have a higher reflectance than other metals when radiated with ultraviolet light of the same wavelength band.

The mixture solution of the resin component and aluminum and silver nanoparticles is a composite of resin and metal, and it may reflect about 90% of the amount of the UV light irradiated to the protection member 200 with the wavelength of 350 nm to 460 nm by the reflectance of the aluminum and silver nanoparticles.

When the mixture solution of the resin component and the metal nanoparticles as the composite material is coated on the reinforcing member 110 to a thickness of 60 μm in case the metal nanoparticles are precipitated at 10 vol % in the mixed solution, modulus near the display panel 100 may increase. For example, since silver Ag nanoparticles (with a diameter of 40 nm to 100 nm) have a high modulus of 150 GPa, the modulus of the mixture solution near the display panel 100 may be effectively increased compared to a single acrylic resin modulus (100 MPA to 300 MPa).

As described above, the reinforcing member 110 and the protection member 200 may be formed outside the bent display panel 100 of the bending area BA. Accordingly, the display panel 100 may reflect UV light through the metal nanoparticles when high intensity UV light is irradiated, thereby preventing panel crack and damage.

When manufacturing the display panel 100, the amount of UV light radiation in the bending area BA, which is vulnerable to high-intensity UV radiation, may be locally controlled through the amount of precipitation of metal nanoparticles contained in the protection member 200.

In addition, when manufacturing the display panel 100, the high-intensity UV light may be reflected through the metal nanoparticles contained in the protection member 200, thereby compensating the compression rigidity of the bending area BA of the display panel 100.

In the embodiment of the present disclosure described above, the protection member 200 may be disposed in the reinforcing member 110 in the bending area BA. However, the present disclosure is not limited thereto and the protection member may be contained in the reinforcing member 110.

In a protection member according to another embodiment of the present disclosure, metal nanoparticles may be contained in the reinforcing member 110 when manufacturing the reinforcing member 110. At this time, the metal nanoparticle layer contained in the reinforcing member 110 may serve as the protection member.

In this instance, the metal nanoparticle layer may have a thickness of about 6 μm at 10 vol %. The reinforcing member 110 may be formed to a thickness of 60 μm as a whole including the metal nanoparticle layer.

The reinforcing member 110 may be formed (or disposed) by coating and curing the mixture solution of the resin component and metal nanoparticles on the display panel.

At this time, the metal nanoparticle layer may be disposed in the reinforcing member 110 to contact the display panel 100, not outside the reinforcing member 110.

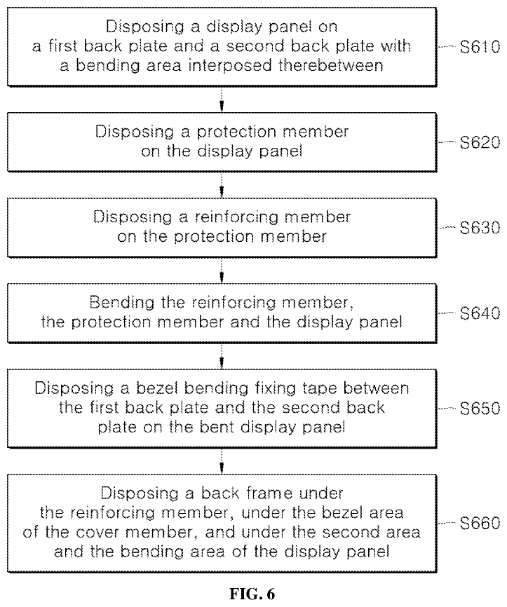

FIG. 6 is a view showing a method for manufacturing a display device according to an embodiment of the present disclosure.

Referring to FIG. 6, the method for manufacturing the display device 1 may include disposing the display panel 100 on the first back plate BP1 and the second back plate BP2 with the bending area BA interposed therebetween (S610).

Here, the optical control layer 140 may be disposed under the display panel 100 and the cover member 20 may be disposed under the optical control layer 140.

The display panel 100 may have one side formed in a flat shape in the active area AA, and may be bonded to the optical control layer 140 by the first adhesive layer AD1. The optical control layer 140 may be bonded to the cover member 20 by the optical clear adhesive OCA layer 150.

Hence, the protection member 200 may be disposed on the display panel 100 (S620). The protection member 200 may be disposed by coating the mixture solution of the resin component and the metal nanoparticles.

The metal nanoparticles may be aluminum Al nanoparticles. The metal nanoparticles may be precipitated at 10 vol % in the mixture solution of the resin component and the metal nanoparticles.

Next, the reinforcing member 110 may be disposed on the protection member 200 (S630).

Hence, the protection member 200, the reinforcing member 110 and the display panel 100 may be bent (S640).

After that, the bezel bending fixing tape 130 may be disposed between the second back plate BP2 and the first back plate BP1 on the bent display panel 100 (S650).

Here, the first back plate BP1 may be disposed under one side of the display panel 100 and the second back plate BP2 may be disposed under the other side of the display panel 100.

One back plate may be disposed under the display panel 100. The first back plate BP1 may be disposed under one side of the display panel 100 and the second back plate BP2 may be disposed under the other side of the display panel 100 by cutting the bending area BA of one back plate. The first back plate BP1 and the second back plate BP2 may be disposed under the display panel, with the bending area BA, which is an empty space, interposed therebetween.

The plate 120 may be disposed under the first back plate BP1. The plate 120 may be fabricated by pressing stainless metal. The plate 120 may be disposed under the first back plate BP1. The plate 120 may be bonded to the first back plate BP1 by the third adhesive layer AD3.

As the display panel 100 is bending, the second back plate BP2 may be positioned on the other side of the bent display panel 100. The other side of the display panel 100 may be bonded to the second back plate BP2 by the sixth adhesive layer AD6. The second back plate BP2 may be bonded to the bent display panel 100 by the sixth adhesive layer AD6.

The bezel bending fixing tape 130 may be disposed between the first back plate BP1 and the second back plate BP2.

Here, the bezel bending fixing tape 130 may be bonded to the plate 120 by the fourth adhesive layer AD4 and the second back plate BP2 by the fifth adhesive layer AD5.

Accordingly, the second back plate BP2 may be bonded to the first back plate BP1 by the bezel bending fixing tape 130 to secure the bent display panel 100.

At this time, the bezel bending fixing tape 130 may be made of at least one of optical clear adhesive OCA, optical clear resin OCR or pressure sensitive adhesive PSA as at least one layer.

Hence, the back frame 30 may be disposed under the protection member 200, under the bezel region BA of the cover member 20, and under the second area 2A and the bending area BA of the display panel 100 (S660).

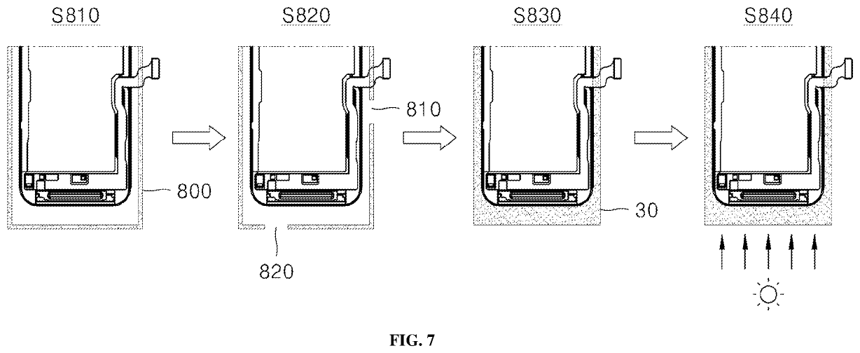

Hereinafter, a process of disposing (or forming) the back frame 30 will be described referring to FIG. 7.

FIG. 7 is a view showing a process of manufacturing a back frame according to an embodiment of the present disclosure.

The back frame 30 according to this embodiment of the present disclosure may be formed to support the display module 17.

Referring to FIG. 2, the area of the display device 1, which is supported by the back frame 30, is an area continued along an outermost edge in left, right and down direction of the display module 17 on the rear surface of the display device 1, except the active area AA.

Referring to FIG. 7, the back frame 30 according to this embodiment of the present disclosure may include a bezel area BZA of the display module 17. A molding guide 800 may be seated on the display module 17 to surround an area continued along the outermost edge in the left, right and down direction of the display module 17 (S810).

At this time, the molding guide 800 may include an injection hole 810 for injecting polymer epoxy resin and a discharge hole 820 for discharging the polymer epoxy resin outside.

After that, the molding guide 800 may be seated to surround the bezel area BZA along the outermost edge on the rear surface of the display device 1.

Next, the polymer epoxy resin may be injected into the injection hole 810 of the molding guide 800 (S820).

At this time, the polymer epoxy resin may be injected into the injection hole 810 of the molding guide 800 until it is discharged from the discharge hole 820 after filled in the molding guide 800.

The polymer epoxy resin injected in the molding guide 800 may be filled in the molding guide 800 to surround the rear surface of the display module 17 of the cover member 20 of the display device 1 in the bezel area BZA, surround the bent display panel 100 of the display device 1 and surround the display panel 100 on the rear surface of the display module 17.

When the polymer epoxy resin is discharged from the discharge hole 820 of the molding guide 800, the injection of the polymer epoxy resin into the injection hole 810 may stop.

When all the polymer epoxy resin filled in the molding guide 800 is discharged through the discharge hole 820 of the molding guide 800, the injection may stop and the molding guide 800 may be demounted from the display device 1 (S830).

When the molding guide 800 is demounted from the display device 1, the polymer epoxy resin may remain along the rear surface of the display module 17 and the bezel area BZA, with a predetermined width and a predetermined thickness.

Next, the polymer epoxy resin filled in the rear surface of the display module 17 and the bezel area BZA may be cured (S840).

At this time, the polymer epoxy resin filled in the rear surface of the display module 17 and the bezel area BZA may be cured by UV light.

The polymer epoxy resin formed along the bezel area BZA on the rear surface of the display device 1 may be cured by UV light. During the process of curing by UV light, a curing catalyst for accelerating the curing may be used to facilitate the curing of the polymer epoxy resin with a small light amount.

The curing means converting a liquid resin into a solid of a polymer. In this process, the back frame 30 may be formed by curing the polymer epoxy resin.

The back frame 30 formed as described above, may support the rear surface of the cover member 20 of the bezel area BZA as shown in FIG. 2, and may support the bending area BA of the display module 17 and the rear surface surrounding the display module 17.

At this time, the back frame 30 may be formed of the polymer epoxy resin so as to cover the lower surface of the protection member 200 disposed outside the reinforcing member 110 of the display panel and the bending area BA.

Table 1 below compares the bezel thickness and modulus of examples and those of experimental examples. Experimental examples may be a metal cover member frame and the embodiment may be the back frame 30 including the polymer epoxy resin.

TABLE 1

| | Experimental | Embodiment |
|---|---|---|
| Category | example | example |
| Bezel thickness | thick Bezel | Narrow bezel |
| Material | Polycarbonate PC | Cured epoxy resin |
| modulus | 2.4 Gpa | 3.35 Gpa |

As shown in Table 1, in the experimental example, since the cover member frame is made of a polycarbonate PC material, for example, there may be a limit to a narrow bezel. In the embodiment example, since the back frame 30 made of the cured polymer epoxy resin has high modulus (or high modulus of elasticity), the back frame 30 with a thinner thickness may be provided, so that narrow bezel may be possible.

Meanwhile, a driving integrated circuit may be disposed on the other surface of the pad of the display panel on which the second back plate BP2 is disposed.

The driving integrated circuit may be mounted on the display panel 100 through a chip bonding process or a surface mounting process. The driving integrated circuit may be disposed under the display panel 100 with respect to the bent state. For example, the drive integrated circuit may be disposed under the pad.

In this instance, a flexible printed circuit (not shown) may be disposed between the pad and the driving integrated circuit board, so that the driving integrated circuit board may be positioned on a rear surface of the flexible printed circuit board FPCB.

The driving integrated circuit may generate a data signal and a gate control signal based on image data and a timing synchronization signal supplied from an external host driving system. After that, the driving integrated circuit may supply the data signal to data lines of pixels through the pad, and may supply a gate control signal to a gate driving circuit (not shown).

The driving integrated circuit may be mounted in a chip mounting area defined by the display panel 100 and electrically connected to the pad to be connected with signal lines of a gate driving circuit and a pixel array unit.

Since the driving integrated circuit generates considerable heat, it is necessary to effectively dissipate heat from the driving integrated circuit. The driving integrated circuit may be primarily dissipated by the support plate.

The pad may be disposed on one side of the display panel 100 in which the driving integrated circuit is mounted.

The pad may be electrically connected with the flexible printed circuit board on which the circuit board is mounted at the rear surface of the display panel 100.

One side of the flexible printed circuit board may be electrically connected with the pad provided on one side of the display panel 100 through a process of bonding a film via a conductive adhesive layer, to be positioned on the rear surface of the display panel 100.

In this instance, the conductive adhesive layer may be an anisotropic conductive film ACF as one example.

The circuit board may provide the image data and the timing synchronization signal supplied from the host driving system to the driving integrated circuit board, and may provide a voltage required to drive the pixel array unit and the gate driving circuit.

The flexible printed circuit board having one side connected with the display panel 100 may extend to bent to a rear surface of the front surface of the display panel 100, together with the display panel 100.

The flexible printed circuit board extending from one side connected with the display panel 100 may be positioned on the rear surface of the display panel 100, which is not covered by the pad of the display panel 100.

Accordingly, at least predetermined area of the flexible printed circuit board may be in contact with the rear surface of the display panel 100.

The display device 1 according to the embodiment of the present disclosure means a display device provided with flexibility only to be used as the same meaning as a bendable display device, a rollable display device, a unbreakable display device, foldable display device, etc.

The driving integrated circuit may be realized as a thin film transistor TFT in the non-display device. Such the driving integrated circuit may be called a gate-in-panel (GIP). The GIP circuit may include a gate drive unit having a GIP structure. At this time, the gate drive unit may be configured of a bottom gate type thin film transistor BG-T. A source of bridge wiring and a drain metal film may extend to be connected with a drain electrode of the BG thin film transistor.

Several components such as a data driver IC may be mounted on a top of a separated printed circuit board, and may be coupled to a connection interface (e.g., a pad/bump, pin, etc.) disposed in the non-display area NA by using a circuit film such as FPCB (flexible printed circuit board), COF (chip-on-film) and TCP (tape-carrier-package). The non-display area NA may bend together with the connection interface so that the printed circuit (e.g., COF, PCT, etc.) may be positioned on the rear surface of the display device 1.

The display device 1 according to the embodiments of the present disclosure may include various additional components for generating various signals or driving pixels PX in the active area. The additional components for driving the pixels may include an inverter circuit, a multiplexer, an electrostatic discharge circuit, etc. The display device 1 according to the present disclosure may include additional components related to a function rather than the function of driving the pixels. For example, the display device 1 according to the present disclosure may include additional components for providing a touch sensing function, a tactile feedback function, etc. The above-mentioned additional components may be disposed on an external circuit connected with the non-display area and/or the connection interface.

Several components of the display device 1 may be bendable along a bending line. The bending line may extend horizontally, vertically or diagonally. Accordingly, the display device 1 according to the embodiment of the present disclosure may be bendable in a direction of combinations of horizontal, vertical and diagonal directions based on a required design.

One or more edges of the display device 1 may be bendable to be farther from a central portion along the bending line. The bending line may be positioned close to the edges of the display device 1 but extended across the central portion or may extend diagonally from one or more edges of the display device 1. The structure may facilitate the display that may be foldable or display on both folded surfaces.

Since one or more portions of the display device 1 are bendable, the display device 1 may be defined by a substantially flat portion and a curved portion. The portion of the display device 1 may be referred to as a substantially flat area. The portion of the display device may be bendable at a preset angle and it may be referred to as the bending area or the curvature area. The curvature area may include a bent section substantially bent with a predetermined bending radius.

The term of “substantially flat” may include areas that are not completely flat. For example, the term may also describe a concave central portion, a convex central portion as substantially flat portions in some embodiments. One or more curved portions may be next to the concave central portion or the convex central portion, and bent inward or outward at an angle to the axis of flexion along the line of curvature. The bending radius of the curvature area is smaller than that of the flat area. In other words, the term of ‘substantially flat’ means a portion having a curvature smaller than adjacent sections.

While a portion in one side of the bending line is positioned toward the center of the display device 1 based on the position of the bending line, the portion in the other side of the bending line is positioned toward the edge of the display device 1. A portion toward the center of the display device 1 may be referred to as a center portion, and a portion toward the edge of the display device 1 may be referred to as an edge portion. Although not always, the center portion of the display device 1 may be substantially flat and the edge portions may be a bent area. The substantially flat portion may also be positioned at the edge portion. In some shapes of the display device 1, the bent section may be disposed between two substantially flat portions.

When the non-display area NA is bent, the non-display area NA may be invisible or minimally visible from the front surface of the display device 1. Some area of the non-display area NA, which is visible from the front surface of the display device 1, may be hidden by the bezel. The bezel may be formed of an independent structure, a housing or other suitable elements. Some area of the non-display area NA that is visible from the front surface of the display device 1 may be hidden under an opaque masking layer such as black ink (e.g., carbon black filled polymer). The opaque masking layer may be provided on various layers (e.g., a touch sensor layer, a polarization layer, a cover layer, etc.) provided in the display device 1.

In several embodiments, the bent area of the display device 1 may include an active area capable of displaying an image. Specifically, the bending line may be disposed in the active area so that at least predetermined pixels of the active area may be included in the curvature portion.

As described above, the embodiments of the present disclosure may realize the display device that may facilitate minimum deformation through the inner structure when stress occurs in the panel bending area of the display device due to an external shock, and may improve screen defect.

Although the present invention has been described with reference to the exemplified drawings, it is to be understood that the present invention is not limited to the embodiments and drawings disclosed in this specification, and those skilled in the art will appreciate that various modifications are possible without departing from the scope and spirit of the present invention. Further, although the operating effects according to the configuration of the present invention are not explicitly described while describing an embodiment of the present invention, it should be appreciated that predictable effects are also to be recognized by the configuration.

[Description of Numeral references]

| | |
|---|---|
| 1: Display device | 17: Display module |
| 20: Cover member | 30: Back frame |
| 100: Display panel | 110: Reinforcing member |
| 120: Plate | 130: Bezel bending fixing tape |
| 140: Polarization layer | 150: Optical clear adhesive |
| 200: Protection member | 800: Molding guide |
| 810: Injection hole | 820: Discharge hole |
| BP1, BP2: Back plate | PAD: Pad |
| AD1 to AD6: Adhesive layer | AA: Active area |
| NA: Non-display area | BZA: Bezel area |
| BA: Bending area | |

What is claimed is:

1. A display device comprising:
a display panel comprising a first area, a second area, a bending area, and a bezel area;
a cover member on the display panel;
a protection member outside of the display panel in the bending area;
a reinforcing member outside of the protection member in the bending area; and
a back frame under the reinforcing member, under the cover member, and under the display panel that is bent,
wherein the back frame supports the reinforcing member, supports the bezel area of the cover member, and supports the first area, the second area, and the bending area of the display panel.

2. The display device of claim 1, wherein the protection member comprises metal nanoparticles.

3. The display device of claim 2, wherein the metal nanoparticles comprise aluminum or silver.

4. The display device of claim 1, wherein the back frame is contact with the bezel area of the cover member, and with the second area of the display panel and the protection member of the bending area.

5. The display device of claim 1, wherein the first area corresponds to an active area of the display panel, the second area comprises the bent display panel, and the first area and the second area face each other in a vertical direction.

6. The display device of claim 5, wherein the display panel has a flat shape in the first area, a downwardly bent shape in the bending area, and a flat shape in the second area.

7. The display device of claim 1, further comprising:
a first back plate under the display panel, the first back plate supporting the display panel in the first area and the bending area;
a second back plate on the bent display panel, the second back plate supporting the display panel in the second area; and
a plate between the first back plate and the second back plate.

8. The display device of claim 7, wherein a connection member that fixes the bent display panel in the bezel area is between the second back plate and the plate.

9. The display device of claim 8, wherein the connection member is made of at least one material of an optical clear adhesive, an optical clear resin, or a pressure sensitive adhesive, as at least one layer.

10. The display device of claim 8, wherein the connection member comprises a tape or a double-sided tape with conductivity that is a foam tape or a foam pad.

11. The display device of claim 7, wherein the plate comprises:
an embossed layer in contact with the first back plate;
a cushion layer under the embossed layer; and
a heat dissipation layer under the cushion layer.

12. The display device of claim 1, wherein the reinforcing member comprises a micro-coating layer.

13. The display device of claim 1, wherein the protection member covers the display panel of the bending area, and a portion of the display panel of the first area in contact with the bending area.

14. The display device of claim 13, wherein the protection member further covers the display panel of the second area.

15. The display device of claim 13, wherein the reinforcing member covers the protection member of the bending area, and covers a portion of the protection member of the first area in contact with the bending area.

16. The display device of claim 15, wherein the reinforcing member further covers the protection member of the second area.

17. A display device comprising:
a display panel comprising a first area, a second area, a bending area, and a bezel area;
a cover member on the display panel;
a reinforcing member outside of the display panel in the bending area; and
a back frame under the reinforcing member, under the cover member, and under the display panel that is bent,
wherein the reinforcing member comprises a metal nanoparticle layer,
the back frame supports the reinforcing member, supports the bezel area of the cover member, and supports the first area, the second area, and the bending area of the display panel.

18. The display device of claim 17, wherein the reinforcing member is a cured mixture solution of a resin component and metal nanoparticles on the display panel.

19. The display device of claim 17, wherein the metal nanoparticle layer is inside the reinforcing member rather than outside the reinforcing member and contacts the display panel.

20. The display device of claim 18, wherein the metal nanoparticles comprise silver.
